(19) United States
(12) Patent Application Publication
(10) Pub. No.: US 2026/0107093 A1
(43) Pub. Date: Apr. 16, 2026

(54) DISPLAY DEVICE AND DISPLAY DEVICE INCLUDING MICROPHONE MODULE

(71) Applicant: LG Display Co., Ltd., Seoul (KR)

(72) Inventor: Taihyeon Ha, Seoul (KR)

(73) Assignee: LG Display Co., Ltd., Seoul (KR)

(21) Appl. No.: 19/267,266

(22) Filed: Jul. 11, 2025

(30) Foreign Application Priority Data
Oct. 11, 2024 (KR) 10-2024-0138234

(51) Int. Cl. H04R 19/04; G06F 3/041; H04R 1/02; H05K 5/00; H05K 5/03; H05K 9/00

(52) U.S. Cl. CPC H04R 19/04; G06F 3/0412; H04R 1/028; H05K 5/0018; H05K 5/03; H05K 9/0067; H04R 2499/15

(57) ABSTRACT

A display device in which a front electrode serving as a diaphragm in a condenser-type microphone module is disposed on one surface of a display panel, and a rear electrode is disposed under a frame, so that a change in capacitance between the front electrode and the rear electrode caused by the vibration of the front electrode is sensed with high sensitivity. Accordingly, the condenser-type high-sensitivity microphone can be integrated into the display device.

### CROSS-REFERENCE TO RELATED APPLICATION

This application claims priority to Korean Patent Application No. 10-2024-0138234, filed on Oct. 11, 2024 in the Korean Intellectual Property Office, the contents of which in its entirety are herein incorporated by reference into the present application.

### BACKGROUND

### Field

The present disclosure relates to a display device, and more particularly, to a display device including a microphone module.

### Description of Related Art

Display devices are implemented in a wide variety of forms, such as televisions, monitors, smartphones, tablet PCs, laptops, wearable devices, and the like.

An organic light-emitting display (OLED) among display devices for displaying various information as an image is a self-luminous device that emits light by itself, and has advantages in that a response speed is fast, light emission efficiency and luminance is high, and a viewing angle are large, and a contrast ratio and color gamut are excellent.

Recently, various functions have been added to the display devices in order to expand the application range of the organic light-emitting display device as well as the user's request for a high-quality image. One of the various functions added thereto in the spotlight is a display microphone function.

### SUMMARY OF THE DISCLOSURE

In this regard, in one example of a combination of the display device and the microphone, a dynamic type microphone can be used. In the dynamic type microphone, a coil moves by a sound wave, and the coil generates a current under a magnetic field. The dynamic type microphone has a relatively simple structure and is highly durable, but has low sensitivity and has a limitation in particularly precise voice recognition.

In another example of the combination of the microphone and the display device, a condenser-type microphone can be used. The condenser-type microphone is a high-sensitivity microphone which converts sound waves into electrical signals. The condenser-type microphone converts sound waves into electrical signals using a change in a capacitance between two metal plates acting as a diaphragm and a fixed electrode. The diaphragm is made of a thin and light conductive material and can vibrate by sound waves. This vibration can change the capacitance between the two electrodes, and the change in the capacitance is converted into an electrical signal to collect the sound. In this process, the condenser-type microphone needs an external power source, and can provide a structure advantageous for high-sensitivity voice recognition.

For example, a display device capable of high-sensitivity voice recognition can be implemented by applying the condenser-type microphone to the organic light-emitting display device. However, when the condenser-type microphone is applied to the organic light-emitting display device, both structural and electrical characteristics of the organic light-emitting display device and the condenser-type microphone should be considered. In particular, due to the thin and flexible characteristics of an organic light-emitting display panel, it can be difficult to effectively integrate and apply the diaphragm of the condenser-type microphone to the organic light-emitting display device.

Accordingly, the present disclosure proposes a new structure for integrating a condenser-type microphone into an OLED panel.

Accordingly, the inventor of the present disclosure has invented a display device having a new structure for integrating a condenser-type microphone into an organic light-emitting display device through various experiments.

A technical purpose to be achieved according to one or more embodiments of the present disclosure is to provide a display device into which a high-sensitivity microphone is integrated.

Another technical purpose to be achieved in accordance with the present disclosure is to provide a display device including a microphone capable of accurately detecting and measuring a change in capacitance between a front electrode and a rear electrode.

Still another technical purpose to be achieved in accordance with the present disclosure is to provide a display device including a microphone that reduces production energy and does not increase a thickness of the display device.

In addition, a technical purpose to be achieved according to an embodiment of the present disclosure is to provide a display device capable of implementing a microphone function with high sensitivity while maintaining touch performance of a display panel.

Purposes according to the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A display device according to an embodiment of the present disclosure includes: a display panel; a cover member disposed on top of the display panel; a front electrode disposed on one side of the display panel; an insulating layer disposed under the display panel; a frame disposed under the insulating layer; and a rear electrode disposed under the frame so as to face the front electrode, wherein the cover member and the frame respectively include a first opening and a second opening, each disposed to overlap the front electrode in a vertical direction, wherein a change in capacitance between the front electrode and the rear electrode caused by vibration of the front electrode is converted into an audio output signal.

According to aspects of the present disclosure, the front electrode can be disposed between the display panel and the insulating layer.

According to aspects of the present disclosure, the display device can further comprise a polarizing layer disposed between the cover member and the display panel, wherein the polarizing layer, the display panel, and the insulating layer vibrate together with the vibration of the front electrode.

According to aspects of the present disclosure, the display device can further comprise a touch layer disposed between the display panel and the polarizing layer.

According to aspects of the present disclosure, the display panel can include a touch layer.

According to aspects of the present disclosure, the front electrode can be disposed between the cover member and the display panel.

According to aspects of the present disclosure, the display device can further comprise a polarizing layer disposed between the cover member and the front electrode, wherein the polarizing layer, the display panel, and the insulating layer vibrate together with the vibration of the front electrode.

According to aspects of the present disclosure, the display device can further comprise a touch panel disposed between the polarizing layer and the cover member.

According to aspects of the present disclosure, the display device can further comprise an antistatic layer made of the same material as the front electrode and disposed in the same layer as the front electrode, wherein the front electrode can be spaced apart from the antistatic layer by a predetermined distance.

According to aspects of the present disclosure, the display device can further comprise: a first wiring electrically connected to the front electrode; a connection electrode layer made of the same material as and disposed in the same layer as the front electrode to electrically connect the front electrode to the first wiring; and a second wiring electrically connected to the rear electrode, wherein a notch can be defined between the front electrode and the connection electrode layer, the notch having a thickness smaller than that of each of the front electrode and the connection electrode layer.

According to aspects of the present disclosure, the front electrode can be a transparent electrode.

According to aspects of the present disclosure, the display panel can include: a display area; a non-display area disposed outside the display area; and a camera area disposed in the display area, wherein the camera area can be closer to one side of the display area than to the other side thereof, wherein the first opening can be disposed adjacent to the camera area and can be closer to one side of the display area than to the other side thereof.

According to aspects of the present disclosure, a portion of the cover member corresponding to the camera area can be unopened.

A display device according to another embodiment of the present disclosure includes: a display panel; a cover member disposed on top of the display panel; a front electrode disposed on one side of the display panel; an antistatic layer made of the same material as a material of the front electrode, wherein the antistatic layer and the front electrode can be disposed in the same layer; an insulating layer disposed under the display panel; a rear electrode disposed under the insulating layer so as to face the front electrode; and a microphone module configured to output a voltage between the front electrode and the rear electrode as an audio signal.

According to aspects of the present disclosure, the front electrode can be disposed between the display panel and the insulating layer.

According to aspects of the present disclosure, the display device can further comprise an adhesive layer disposed between the front electrode and the insulating layer, wherein the front electrode can be a deposition layer deposited on the display panel.

According to aspects of the present disclosure, the front electrode can be disposed between the cover member and the display panel.

According to aspects of the present disclosure, the display device can further comprise an adhesive layer disposed between the display panel and the insulating layer, wherein the front electrode can be a deposition layer deposited on the display panel.

According to aspects of the present disclosure, the cover member has a first area overlapping the front electrode in a vertical direction, wherein a thickness of the first area in the vertical direction is smaller than a thickness of the cover member outside the first area.

According to aspects of the present disclosure, the cover member can have a first area disposed to overlap the front electrode in a vertical direction, wherein the first area can be entirely opened.

According to aspects of the present disclosure, the frame can have an opening defined therein and overlapping the front electrode in a vertical direction.

According to aspects of the present disclosure, the front electrode can include indium tin oxide (ITO), wherein the insulating layer can include a polymer material.

According to an embodiment of the present disclosure, the front electrode serving as a diaphragm in the condenser-type microphone module is disposed on one side of the display panel, and the rear electrode is disposed under the frame, thereby enabling high-sensitivity detection of the change in capacitance between the front electrode and the rear electrode caused by the vibration of the front electrode. Accordingly, the condenser-type high-sensitivity microphone can be integrated into a display device.

In addition, according to an embodiment of the present disclosure, forming openings in both the cover member and the frame that vertically overlap the front electrode prevents the vibration of the front electrode due to external sound from being hindered by the cover member and the frame. The display device can accurately detect and measure the change in capacitance between the front electrode and the rear electrode.

In addition, according to an embodiment of the present disclosure, the front electrode is configured to be formed of the same material as the antistatic layer and in the same layer as the antistatic layer. Accordingly, the electrode performing a diaphragm function of the microphone and the layer performing an antistatic function of the display panel can be formed in a single process.

According to aspects of the present disclosure, through such process optimization, the microphone function and the antistatic function can be implemented in the same process without separate processes or an additional layer formation. This optimizes the manufacturing process by integrating the microphone and antistatic functions without additional processes or layers, thereby reducing energy consumption while maintaining the thin profile of the display device.

In addition, according to an embodiment of the present disclosure by disposing the front electrode adjacent to the non-touch-functional camera area of the display device, signal interference between the touch-sensitive layer and the front electrode is effectively minimized. Accordingly, there is an effect of implementing a microphone function with high sensitivity while maintaining the touch performance of the display panel.

Effects of the present disclosure are not limited to the effects mentioned above, and other effects not mentioned will be clearly understood by those skilled in the art from the description as set forth below. In addition to the above effects, specific effects of the present disclosure are described together while describing specific details for carrying out the present disclosure.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a view of a display device according to an embodiment of the present disclosure.

FIG. 2 is a diagram illustrating a structure of a condenser-type microphone according to an embodiment of the present disclosure.

FIG. 3 is a diagram of a display device according to another embodiment of the present disclosure, and an enlarged view of a microphone area.

FIG. 4 is a side cross-sectional view of a display device including a microphone module according to an embodiment of the present disclosure.

FIG. 5 is an enlarged side cross-sectional view of a partial area of the display device of the embodiment of FIG. 4.

FIG. 6 is a side cross-sectional view of a display device including a microphone module according to another embodiment of the present disclosure.

FIG. 7 is a side cross-sectional view of a display device including a microphone module according to still another embodiment of the present disclosure.

FIG. 8 is a side cross-sectional view of a display device including a microphone module according to still yet another embodiment of the present disclosure.

FIG. 9 is an enlarged side cross-sectional view of a partial area of the display device according to the embodiment of FIG. 8.

FIG. 10 is a side cross-sectional view of a display device including a microphone module according to still yet another embodiment of the present disclosure.

### DETAILED DESCRIPTIONS OF THE EMBODIMENTS

Advantages and features of the present disclosure, and a method of achieving the advantages and features will become apparent with reference to embodiments described below in detail together with the accompanying drawings. However, the present disclosure is not limited to the embodiments as disclosed under, but can be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims. A shape, a size, a ratio, an angle, a number, etc. disclosed in the drawings for illustrating embodiments of the present disclosure are illustrative, and the present disclosure is not limited thereto. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements can modify an entirety of the list of elements and may not modify the individual elements of the list. In interpretation of numerical values, an error or tolerance therein can occur even when there is no explicit description thereof. In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when a first element or layer is referred to as being “connected to”, or “coupled to” a second element or layer, the first element can be directly connected to or coupled to the second element or layer, or one or more intervening elements or layers can be present therebetween. In addition, it will also be understood that when an element or layer is referred to as being “between” two elements or layers, it can be the only element or layer between the two elements or layers, or one or more intervening elements or layers can also be present therebetween. Further, as used herein, when a layer, film, area, plate, or the like is disposed “on” or “on a top” of another layer, film, area, plate, or the like, the former can directly contact the latter or still another layer, film, area, plate, or the like can be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former can directly contact the latter or still another layer, film, area, plate, or the like can be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated. When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved. It will be understood that, although the terms “first”, “second”, “third”, and so on can be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment of the present disclosure can be implemented differently, functions or operations specified within a specific block can be performed in a different order from an order specified in a flowchart. For example, two consecutive blocks can actually be performed substantially simultaneously, or the blocks can be performed in a reverse order depending on related functions or operations. The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, “embodiments,” “examples,” “aspects, etc. should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there can be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term can be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions. In description of flow of a signal, for example, when a signal is delivered from a node A to a node B, this can include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified. As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but can be interpreted as having a geometric relationship with each other in which the first direction, the second direction, and the third direction intersect each other at an angle other than 90 degrees or the X-axis direction, the Y-axis direction, and the Z-axis direction are intersect each other at an angle other than 90 degrees within a range in which a configuration of the present disclosure can work functionally. Further, the term “can” fully encompasses all the meanings and coverages of the term “may” and vice versa.

Hereinafter, a display device including a microphone according to various embodiments of the present disclosure will be described in detail with reference to the drawings. All the components of each display device or apparatus according to all embodiments of the present disclosure are operatively coupled and configured.

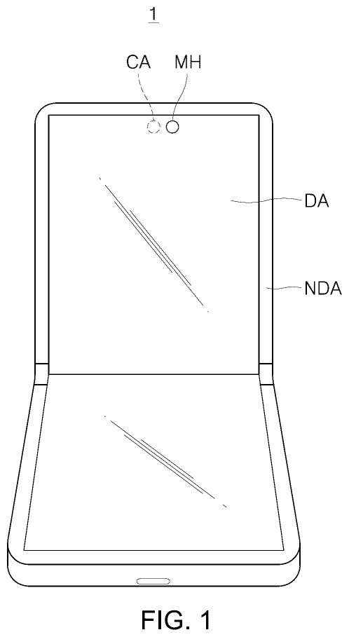

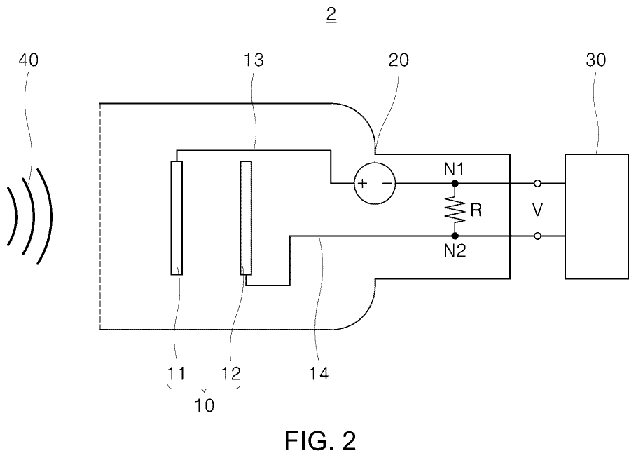

FIG. 1 is a view of a display device according to an embodiment of the present disclosure. FIG. 2 is a diagram illustrating a structure of a condenser-type microphone according to an embodiment of the present disclosure.

Referring to FIGS. 1 and 2, an example in which the display device 1 is embodied as an organic electroluminescence display device (Organic Light-emitting Diodes Display Device) is described below. However, embodiments of the present disclosure are not limited thereto.

The display device 1 can include a display area DA and a non-display area NDA. The display area DA is an area in which a plurality of sub-pixels are disposed to substantially display an image. The display area DA can include not only sub-pixels for displaying an image, but also various driving elements and circuit elements for driving the sub-pixels. The non-display area NDA is an area in which an image is not substantially displayed, and can be disposed to surround the display area DA. The non-display area NDA can be referred to as a bezel area. In the non-display area NDA, various types of lines, a gate driver IC, a data driver IC, and a printed circuit board for driving the driving elements and the circuit elements disposed in the display area DA can be disposed.

In one example, a camera area CA and a microphone area MH can be disposed in the display area DA. The camera area CA is an area in which a photographing device such as a camera module is disposed under an area of a display panel corresponding to the display area DA. The camera area CA can be an area in which an image is not displayed or which has a lower resolution than that of the display area around the camera area CA.

For example, the display device 1 according to an embodiment of the present disclosure can be implemented in an under display camera (UDC) structure. The UDC structure is a structure in which the camera is integrated with the display panel while being positioned under the display panel so that the camera module is screened with the display screen and is not visible to a viewer. Such a structure has the advantage of maintaining a camera function while providing a wider screen because there is no need to provide a hole or a notch in the display screen. This UDC structure can be applied to various display devices such as smartphones, tablets, and laptops. An example in which the display device 1 illustrated in FIG. 1 is embodied as a foldable display device is illustrated. However, the present disclosure is not limited thereto.

In the UDC structure, in one example, a portion of the display area corresponding to the camera area CA normally displays a display screen in a display mode. In the camera mode, the portion of the display area corresponding to the camera area CA is deactivated or transparent such that the camera receives external light. In addition, in a touch display device 1 including a touch function, a touch layer implementing the touch function may not be disposed in an area corresponding to the camera area CA or an area adjacent thereto. The camera area CA can be disposed closer to one side of the display area DA than to the other side thereof. For example, the camera area CA can be disposed at one of both opposing sides at the top of the display device 1.

In order to provide various functions and convenience, the display device 1 can include components such as an illuminance sensor, an object recognition sensor and/or a biometric sensor as well as a camera module. These components can be formed in the display panel 100 so as to overlap the camera area CA or can be formed adjacent to the camera area CA.

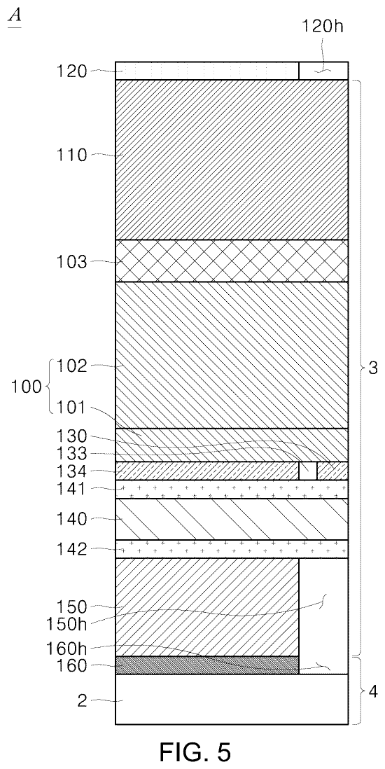

In one example, the microphone area MH can be positioned adjacent to the camera area CA while being closer to one side of the display area DA than to the other side thereof. The microphone area MH is an area in which the microphone module 4 (see FIG. 5) included in the display panel 100 is disposed. Referring to FIG. 2, a microphone module 4 according to an embodiment of the present disclosure includes a condenser-type microphone 2.

The condenser-type microphone 2 can be implemented using a condenser including two flat plate-shaped electrodes. The condenser-type microphone 2 can convert a sound signal into an electrical signal using a principle in which the capacitance of the condenser changes based on a sound.

The microphone 2 can include a condenser 10 and a power supply 20 for driving the condenser 10. The condenser 10 is composed of two flat-plate electrodes including a front electrode 11 and a rear electrode 12. The front electrode 11 can be connected to the power supply 20. However, the power supply 20 can be connected to the rear electrode 12. In order to effectively detect a change in capacitance of the condenser, the front electrode 11 is preferably embodied as a diaphragm made of a conductive material. For example, the front electrode 11 can be embodied as a transparent electrode made of, for example, ITO or IZO. However, embodiments of the present disclosure are not limited thereto.

When the sound 40 generated from the outside out of the microphone 2 vibrates the front electrode 11 embodied as the diaphragm made of a conductive material, a distance between the front electrode 11 and the rear electrode 12 changes. This change in the distance causes a change in the capacitance of the condenser 10, which can be the basis for converting a sound signal into an electrical signal.

When a voltage is not applied to the condenser 10, the capacitance does not change even if a distance change between the front electrode 11 and the rear electrode 12 occurs due to an external sound. Therefore, a component for applying the power to the condenser 10 is required. FIG. 2 shows a scheme of applying a voltage to the condenser 10 by connecting the power supply 20 to the front electrode 11. This power supply 20 can be embodied as a battery built into the microphone 2 or can employ a DC power located outside the microphone 2. In addition, in order to prevent an overcurrent from flowing from the power supply 20 to the condenser 10, a resistor R can be additionally connected to and disposed between the power supply 20 and the rear electrode 12.

The microphone 2 can include a first wiring 13 and a second wiring 14, and the first wiring 13 and the second wiring 14 can be electrically connected to the front electrode 11 and the rear electrode 12, respectively. The power supply 20 can be connected to the first wiring 13, and can be connected to a first node N1 of the resistor R. The second wiring 14 can be connected to a second node N2 of the resistor R. An output voltage V can be measured based on a voltage between the first wiring 13 and the second wiring 14.

When the capacitance of the condenser 10 changes, the output voltage V changes, which can be recognized and processed as a change in a voice signal in an external system connected to the condenser-type microphone 2. For example, the external system can be a microphone receiver 30. Since the change in the output voltage V can be slight, an amplifier using a transistor or an operational amplifier can be additionally included to amplify the change.

The display panel of the organic light-emitting diode display device according to an embodiment of the present disclosure can vibrate by sound. Thus, this display panel can be combined with the flat type electrode to constitute the condenser, thereby implementing the microphone 2 having a novel structure.

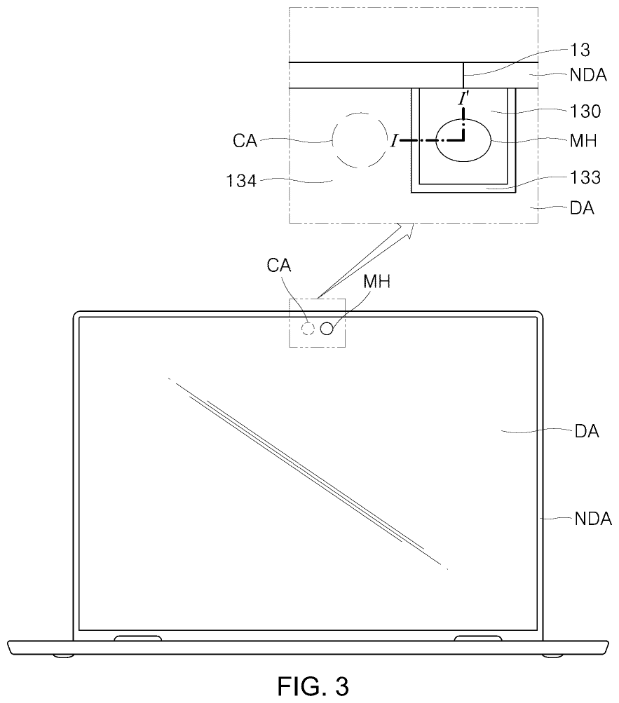

Hereinafter, a display panel including a microphone according to an embodiment of the present disclosure will be described with reference to FIGS. 3 to 5.

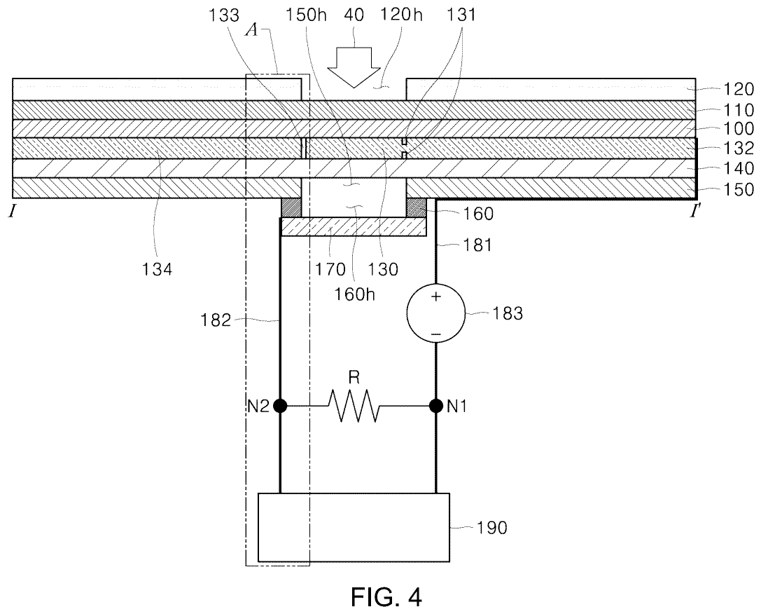

FIG. 3 illustrates a notebook PC as an example of the display device 1. However, the present disclosure is not limited thereto. FIG. 4 is a side cross-sectional view of an area I-I′ in the vicinity of the microphone area MH in FIG. 3, and FIG. 5 is a cross-sectional view illustrating a more specific stacked structure of a partial area A of FIG. 4.

Referring to FIGS. 3 to 5, the display panel 100 can include a substrate 101 supporting a lower surface of the display panel 100 and a display element layer 102. The substrate 101 can include a polymer material such as polyimide, polyamide-imide, polyethersulfone, polyethylene terephthalate, polycarbonate, or the like. However, embodiments of the present disclosure are not limited thereto. The display element layer 102 including an organic light-emitting element and a circuit area for driving the organic light-emitting element can be disposed on the substrate 101. The circuit area can include thin-film transistors for driving the organic light-emitting element. The organic light-emitting element can include an anode, a cathode, and an organic light-emitting layer positioned therebetween. In the organic light-emitting element, holes injected from the anode and electrons injected from the cathode are combined with each other in the organic emission layer to emit light, thereby displaying an image.

As illustrated in FIG. 5, a touch layer 103 can be separately provided on the display panel 100 and can be disposed on the display panel 100. Alternatively, the display panel 100 may comprise a touch layer. The touch display device provided with the touch layer 103 is a device for sensing a user's touch input such as a screen touch or a gesture. The touch sensing scheme can be of a resistive type, a capacitive type, an optical type, or an electromagnetic type. The display device operating in this scheme can be implemented as an on-cell touch type touch display device.

However, the present disclosure is not limited thereto. In another example, the display panel 100 can be a touch display panel including a touch function. The display device operating in this scheme can be implemented as an in-cell touch type touch display device.

A polarizing layer 110 can be disposed on the display panel 100. The polarizing layer 110 selectively transmits light therethrough, thereby reducing reflection of external light incident on the display panel 100. Specifically, since the display panel 100 includes various metal layers used in a thin-film transistor, various wires, organic light-emitting elements, and the like, external light incident on the display panel 100 can be reflected from the metal layer, thereby deteriorating visibility of the display device 1. However, when the polarizing layer 110 is applied thereto, external light can be absorbed thereby to improve an ambient contrast ratio of the display device 1. However, a configuration of the display device 1 shown in FIGS. 4 and 5 is merely an example, and the polarizing layer 110 can be omitted according to another embodiment of the present disclosure.

A cover member 120 for protecting the display panel 100 from external impact, scratches, moisture, and the like can be disposed on the polarizing layer 110. The cover member 120 may be disposed on top of the display panel 100. The cover member 120 can be made of a transparent material having excellent impact resistance and scratch resistance, and can prevent external moisture penetration to prevent deterioration and quality degradation of the organic light-emitting display panel 100.

For example, the cover member 120 can be made of a glass material. However, embodiments of the present disclosure are not limited thereto. In another example, the cover member 120 can be a film composed of various polymers such as polyimide, polyamide imide, polyethylene terephthalate, polymethyl methacrylate, polypropylene glycol, polycarbonate, and the like. In addition, the cover member 120 can include a multilayer structure in which various functional layers such as an external light reflection reduction layer, a UV blocking layer, a hard coating layer, etc. are stacked.

In one example, a front electrode 130 can be disposed on one side of the display panel 100, for example, a lower side of the display panel 100. As described above, the front electrode 130 acts as a layer that functions as the diaphragm of the microphone 2 and is a layer that vibrates in response to a sound 40. The front electrode 130 can be disposed in an area corresponding to the microphone area MH. In order for the front electrode 130 to vibrate well in response to the sound 40, a first opening 120h can be formed so as to extend through, in the vertical direction, the cover member 120 and can be positioned in an area overlapping the front electrode 130 in the vertical direction. That is, the first opening 120h can serve as a passage through which the sound 40 can be transmitted. The first opening 120h can be formed in a position corresponding to the microphone area MH. Accordingly, the first opening 120h can also be disposed adjacent to the camera area CA disposed inside the display area DA and can be closer to one side of the display area DA than to the other side thereof. In this case, a portion of the cover member 120 corresponding to the camera area CA may not be opened. As described above, for example, the camera area CA can have the UDC structure. The first opening 120h can be formed in various shapes such as a circle, an oval, a semicircle, and a polygon in a plan view. For example, when the shape in the plan view of the microphone area MH is circular, the first opening 120h can also be formed in a circular shape in the plan view.

Since the sound 40 generally does not pass through a thick glass material, the first opening 120h can be defined in the cover member 120 so that the sound 40 can be well transmitted to the front electrode 130. Accordingly, the sound 40 having passed through the first opening 120h of the cover member 120 can be transmitted to the front electrode 130 to vibrate the front electrode 130. In this case, the polarizing layer 110 and the display panel 100 disposed on the front electrode 130 can vibrate together when the front electrode 130 vibrates.

A size of the first opening 120h can be adjusted according to a size of the microphone module 4. For example, the first opening 120h can be equal to, smaller than, or larger than the size of the microphone module 4. The size of the first opening 120h can be appropriately changed according to the size of the microphone module 4 while maintaining the rigidity and function of the cover member 120. For example, the size of the first opening 120h can be 1 mm or greater. However, embodiments of the present disclosure are not limited thereto.

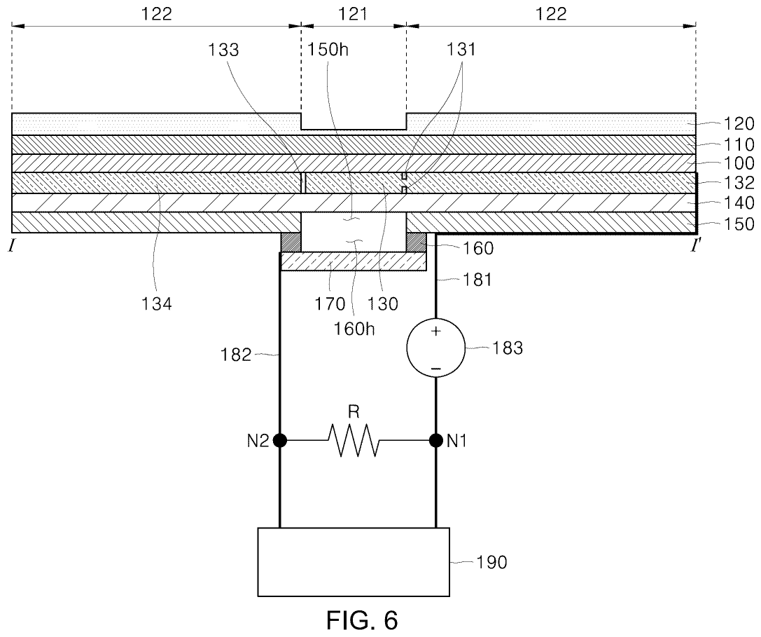

In still another embodiment of the present disclosure, referring to FIG. 6, a thickness in the vertical direction of a first area 121 of the cover member 120 disposed to overlap the front electrode 130 in the vertical direction can be smaller than a thickness of the cover member 120 outside the first area 121, or smaller than a thickness in the vertical direction of a second area 122 of the cover member 120 other than the first area 121 that does not overlap the front electrode 130 in the vertical direction.

As described above, since the first area 121 of the cover member 120 is formed to have a small thickness without being entirely opened, the sound 40 can pass through the first area 121 of the cover member and can transmit the vibration to the front electrode 130. Accordingly, the cover member 120 can prevent the polarizing layer 110 and the display panel 100 disposed thereunder from being exposed to the outside to protect the same, and can also serve to transmit the vibration to the front electrode 130. The thickness of the first area 121 of the cover member 120 is sized such that the sound 40 can pass through the first area 121. In this regard, the thickness is not particularly limited. In this case, as in the embodiment according to FIG. 4, in order to maximize the vibration transfer caused by the sound to the front electrode 130, the first opening 120h can be formed in the cover member 120 by entirely opening the first area 121 of the cover member 120.

In one example, an antistatic layer 134 can be formed in the same layer as the layer of the front electrode 130. For example, the front electrode 130 and the antistatic layer 134 can be formed in the same layer and can be made of the same material and can be formed in one same process. For example, each of the front electrode 130 and the antistatic layer 134 can also be a deposition layer deposited using a deposition process. As described above, the front electrode 130 can be a transparent electrode such as ITO or IZO, and the antistatic layer 134 can be embodied as a transparent electrode such as ITO or IZO. The antistatic layer 134 can be a layer grounded to a ground to discharge static electricity generated in the display panel 100 to the outside.

The front electrode 130 and the antistatic layer 134 may not be continuously connected to each other and can be disposed to be spaced apart from each other by a predetermined distance. That is, the front electrode 130 and the antistatic layer 134 can be formed in the same layer, but can be disconnected from each other. For example, referring to FIG. 3, a gap 133 can be formed between the front electrode 130 and the antistatic layer 134 to form a predetermined distance. As the gap 133 is formed between the front electrode 130 and the antistatic layer 134, the front electrode 130 and the antistatic layer 134 can have different functions.

Referring to in a plan view of FIG. 3, a size of an edge of the front electrode 130 along which the gap 133 defined between the front electrode 130 and the antistatic layer 134 extends can be larger than a size of another edge of the front electrode 130 along which the gap 133 defined between the front electrode 130 and the antistatic layer 134 does not extend. As described above, since the front electrode 130 and the antistatic layer 134 are spaced apart from each other by the gap 133, and the size of an edge of the front electrode 130 along which the gap 133 defined between the front electrode 130 and the antistatic layer 134 extends is larger than the size of another edge of the front electrode 130 along which the gap 133 defined between the front electrode 130 and the antistatic layer 134 does not extend, the front electrode 130 can be more sensitively vibrated by the sound 40.

In an example, in FIG. 3, the front electrode 130 is formed in an approximately rectangular shape in the plan view, and each of three of the four side surfaces of the front electrode 130 faces the antistatic layer 134 such that the gap 133 is defined therebetween. However, a connection electrode layer 132 can be formed on one side surface of the front electrode 130 opposite to the antistatic layer 134 such that the gap is not defined therebetween. However, a shape of the front electrode 130 composed of the four side surfaces in the plan view is only an example, and the shape of the front electrode 130 is not limited thereto.

The connection electrode layer 132 can be formed on one side surface of the front electrode 130 not defining the gap 133 and can be connected to the front electrode 130. The connection electrode layer 132 can be formed in the same layer as that of the front electrode 130 and the antistatic layer 134 in one same process and can be made of the same material as that thereof. The connection electrode layer 132 can be disposed between the front electrode 130 and the non-display area NDA. One side surface of the connection electrode layer 132 can be connected to the front electrode 130, and the other side surface thereof can be electrically connected to a first wiring 181 of the microphone 2 extending from the non-display area NDA. That is, the connection electrode layer 132 can function as an electrical connection intermediate layer for electrically connecting the front electrode 130 and the first wiring 181 to each other.

The front electrode 130 and the connection electrode layer 132 can be electrically connected to each other while a notch 131 is defined therebetween. A thickness of the notch 131 can be smaller than a thickness of each of the front electrode 130 and the connection electrode layer 132. For example, the notch 131 can be formed in a shape such as a bottle neck, such that the front electrode 130 can be prevented from being fixed to the connection electrode layer 132 and thus can prevent the vibration of the front electrode from being insensitive to the sound. Accordingly, the notch 131 can function as a vibration axis of the front electrode 130 that allows the front electrode 130 to vibrate in the vertical direction in a state in which the connection electrode layer 132 is fixed thereto.

An insulating layer 140 can be disposed under the connection electrode layer 132, the antistatic layer 134, and the front electrode 130. The insulating layer 140 can be referred to as a back plate. The insulating layer 140 can support the lower surface of the display panel 100 and protect the lower surface thereof from external impact or foreign substances. In addition, the insulating layer 140 can function to prevent deformation or sagging of the substrate 101 of the display panel 100 having a small thickness. For example, the insulating layer 140 can include various polymer materials such as polyimide (PI), polymethyl methacrylate (PMMA), polycarbonate (PC), polyvinyl alcohol (PVA), acrylonitrile-butadiene-styrene (ABS), polyethylene terephthalate (PET), silicone, polyurethane (PU), and the like. However, embodiments of the present disclosure are not limited thereto.

For example, the insulating layer 140 can be made of the same material as that of the substrate 101 of the display panel 100. When the microphone module 4 is disposed on the rear surface of the display panel 100, each of the substrate 101 and the insulating layer 140 is preferably made of a thin polymer material to facilitate transmission of the sound therethrough. For example, each of the substrate 101 and the insulating layer 140 can include polyimide. The insulating layer 140, the polarizing layer 110 and the display panel 100 can vibrate together with the vibration of the front electrode 130 when the front electrode 130 vibrates.

A first adhesive layer 141 can be disposed between the connection electrode layer 132, the antistatic layer 134, and the front electrode 130 and the insulating layer 140. Accordingly, the insulating layer 140 can be fixed to a lower surface of the connection electrode layer 132 disposed under the display panel 100 via the first adhesive layer 141. For example, the first adhesive layer 141 can be made of an optical clear adhesive (OCA), a pressure sensitive adhesive (PSA), or the like. However, embodiments of the present disclosure are not limited thereto. A frame 150 can be disposed under the insulating layer 140. A second adhesive layer 142 can be disposed between the insulating layer 140 and the frame 150, and the second adhesive layer 142 can be made of the same material as that of the first adhesive layer 141. Accordingly, the frame 150 can be fixed to the lower surface of the insulating layer 140 via the second adhesive layer 142.

The frame 150 is an element for firmly supporting the lower surface of the display panel 100, and can also be referred to as a bottom plate. The frame 150 can be embodied as a metal plate made of a metal material such as stainless steel (SUS), iron (Fe), Invar, aluminum (Al), magnesium (Mg), or the like. For example, stainless steel (SUS) provides high resilience and rigidity, so that the display panel 100 can be stably supported by the frame 150 while the frame 150 maintains mechanical properties even in a small thickness.

The frame 150 can be disposed to overlap the front electrode 130 in the vertical direction, and can include a second opening 150h extending in the vertical direction through the frame 150. Accordingly, the first opening 120h, the front electrode 130, and the second opening 150h can be disposed to overlap each other in the vertical direction.

Since the sound 40 generally does not pass through the metal material well, it is preferable that the frame 150 is opened to have the second opening 150h. That is, the second opening 150h can serve as a passage through which the sound 40 can transmit. The second opening 150h can be formed to correspond to and overlap with the microphone area MH. The second opening 150h can be formed in various shapes such as a circle, an oval, a semicircle, and a polygon in a plan view. For example, when the shape in a plan view of the microphone area MH is circular, the second opening 150h can also be formed in a circular shape in a plan view.

The size in the plan view of the second opening 150h can be adjusted according to the size in the plan view of the microphone module 4. For example, the size of the second opening 150h can be equal to, smaller than, or larger than the size of the microphone module 4. The size of the second opening 150h can be appropriately set according to the size of the microphone module 4 and can be set so as to maintain the rigidity and function of the frame 150. For example, the size of the second opening 150h can be 1 mm or greater. However, embodiments of the present disclosure are not limited thereto.

The stacked structure including the cover member 120, the polarizing layer 110, the display panel 100, the front electrode 130, the insulating layer 140, the frame 150, and the like described above can constitute a panel assembly 3. The microphone 2 can be disposed under the panel assembly 3. The microphone 2 can be fixed to the lower surface of the frame 150 via an adhesive portion 160. The adhesive portion 160 can be made of the same material as that of each of the first adhesive layer 141 and the second adhesive layer 142. The adhesive portion 160 can be disposed to overlap the front electrode 130 in the vertical direction, and can include a third opening 160h extending in the vertical direction through the adhesive portion 160. Accordingly, the first opening 120h, the front electrode 130, the second opening 150h, and the third opening 160h can be disposed to overlap each other in the vertical direction. The microphone 2 together with the adhesive portion 160 can constitute the microphone module 4. The adhesive portion 160 can function as a kind of encapsulation layer.

A rear electrode 170 can be disposed under the adhesive portion 160. The rear electrode 170 may be disposed under the frame 150. For example, the second opening 150h and the third opening 160h can be disposed to overlap each other in the vertical direction. Accordingly, the lower surface of the insulating layer 140 can be exposed to the outside through the second opening 150h and the third opening 160h, and the rear electrode 170 can be disposed to cover the third opening 160h. As described above, the rear electrode 170 is disposed to face the front electrode 130 with the insulating layer 140 interposed therebetween, and thus the rear electrode 170 and the front electrode 130 can constitute the condenser of the microphone 2.

The microphone 2 can include the first wiring 181 electrically connected to the front electrode 130 and the second wiring 182 electrically connected to the rear electrode 170. The display panel 100 can vibrate in response to the sound generated from the outside, and thus the front electrode 130 coupled to the display panel 100 also vibrates. Accordingly, the distance between the front electrode 130 and the rear electrode 170 is changed, and the capacitance of the condenser composed of the front electrode 130 and the rear electrode 170 is changed.

In order to change the capacitance of the condenser composed of the front electrode 130 and the rear electrode 170, an electric field should be generated between the front electrode 130 and the rear electrode 170. To this end, the front electrode 130 or the rear electrode 170 is connected to the power supply 183, and then a voltage should be applied across the front electrode 130 and the rear electrode 170 through the power supply 183. When the display panel 100 vibrates due to the sound generated from the outside, and the capacitance of the condenser composed of the front electrode 130 and the rear electrode 170 changes, the voltage of the condenser also changes. At this time, when the voltage of the condenser is output to the microphone receiver 190, the microphone receiver 190 can recognize the change in the voltage V as a change in the voice signal and process the signal. The microphone receiver 190 can be referred to as a host system. As described above, in the microphone 2 according to the present disclosure, the change in capacitance between the front electrode 130 and the rear electrode 170 due to the vibration of the front electrode 130 can be converted into an audio output signal. That is, the microphone 2 can output the voltage between the front electrode 130 and the rear electrode 170 as the audio signal.

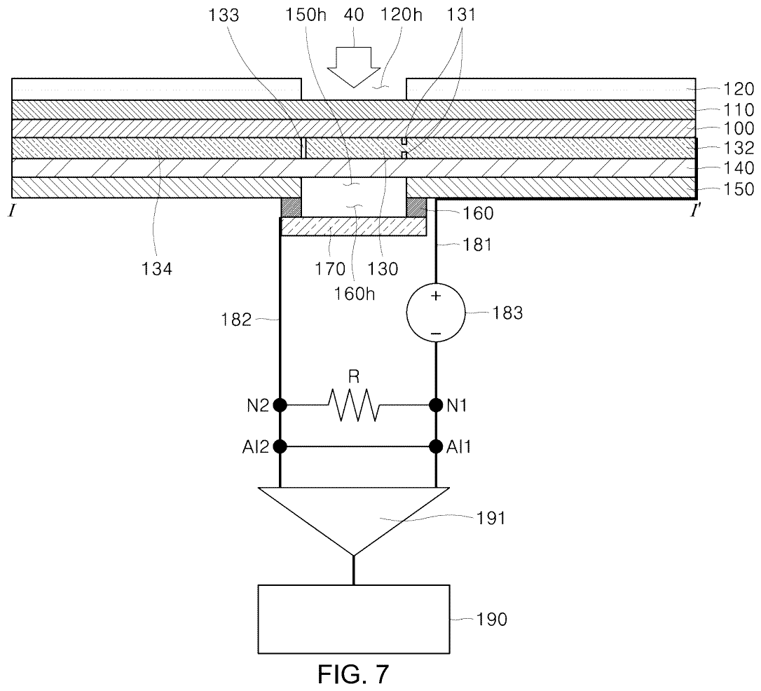

Referring to FIG. 7, the microphone 2 of the display device 1 according to another embodiment of the present disclosure can further include an amplifier 191. The display panel 100 vibrates so finely that humans cannot recognize the vibration, and accordingly, the capacitance and voltage of the condenser can be finely changed. Thus, such a minute change can be distorted by noise. Thus, in accordance with the present disclosure, the amplifier 191 is provided at a terminal for outputting the voltage of the condenser as shown in FIG. 7, so that the voltage of the condenser can be amplified by the amplifier and output therefrom. The amplifier 191 can be embodied as a transistor or an operational amplifier.

The microphone module 4 including the amplifier 191 can include a resistor R, a first node N1, and a second node N2. One end of the power supply 183 can be connected to the front electrode 130, and the other end thereof can be connected to the first node N1. One end of the resistor R can be connected to the first node N1, and the other end thereof can be connected to the second node N2, thereby preventing an overcurrent from flowing.

The rear electrode 170 can be connected to the second node N2 via the second wiring 182, and a first input terminal AI1 of the amplifier 191 can be connected to the first node N1 and a second input terminal AI2 can be connected to the second node N2. The amplifier 191 amplifies a voltage difference between a voltage of the first node N1 and a voltag4e of the second node N2 into which the voltage V of the condenser is divided and outputs the amplified voltage difference as the amplified voltage to the microphone receiver 190, and the microphone receiver 190 can recognize the change in the amplified voltage as a change in the audio signal and process the signal based on the recognition result.

According to the embodiment of the present disclosure described above, the front electrode 130 serving as the diaphragm in the condenser-type microphone module 4 is disposed on one side of the display panel 100, and the rear electrode 170 is disposed under the frame 150, so that a change in capacitance between the front electrode 130 and the rear electrode 170 caused by the vibration of the front electrode 130 can be detected with high sensitivity. Accordingly, the condenser-type high-sensitivity microphone 2 can be integrated into the display device 1.

In addition, according to an embodiment of the present disclosure, the first opening 120h and the second opening 150h are respectively formed in the cover member 120 and the frame 150 and overlap the front electrode 130 in the vertical direction, so that the vibration of the front electrode 130 due to the external sound may not be disturbed by the cover member 120 and the frame 150. Accordingly, the change in capacitance between the front electrode 130 and the rear electrode 170 can be accurately sensed and measured.

According to an embodiment of the present disclosure, the front electrode 130 can be designed to be made of the same material as that of and can be formed in the same layer as that of the antistatic layer 134. Accordingly, the electrode performing a diaphragm function of the microphone 2 and the layer performing an antistatic function of the display panel 100 can be formed in a single process.

Through such process optimization, the microphone function and the antistatic function can be implemented in the same process without separate processes or an additional layer formation. This can reduce the production energy of the display device, and allow for integrating the high-sensitivity condenser microphone with the display device without increasing the thickness of the display device.

In addition, according to an embodiment of the present disclosure, the front electrode 130 can be disposed adjacent to the camera area CA in which the touch function of the display device is not implemented, such that the interference problem between the layer implementing the touch function and the front electrode can be effectively reduced. Accordingly, there is an effect of implementing a microphone function with high sensitivity while maintaining the touch performance of the display panel.

According to an embodiment of the present disclosure, when a separate touch layer 103 is formed between the display panel 100 and the polarizing layer 110, the front electrode 130 is preferably disposed between the display panel 100 and the insulating layer 140 in order to reduce a signal interference of the front electrode 130 by the touch layer 103. Accordingly, since the front electrode 130 can be disposed to be spaced apart from the touch layer 103 with the display panel 100 interposed therebetween, the signal interference caused by the touch layer 103 can be reduced.

According to an embodiment of the present disclosure, even when the display panel 100 is implemented as a touch display panel including a touch function, in order to reduce the signal interference of the front electrode 130 by the touch layer 103, the front electrode 130 is preferably disposed between the display panel 100 and the insulating layer 140. In this case, the substrate 101 constituting the lower surface of the display panel 100 can space the front electrode 130 from the layer performing the touch function in the display panel 100 by a predetermined distance, such that the signal interference caused by the touch display panel can be reduced.

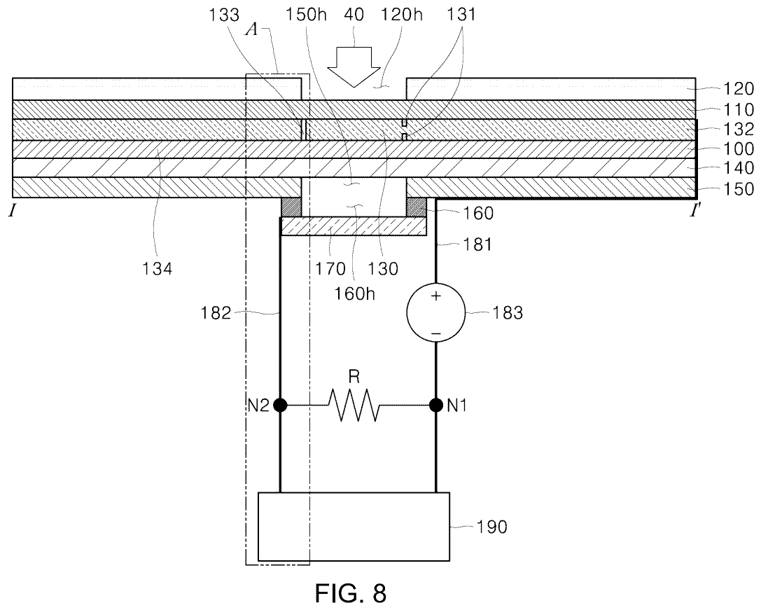

A display device 1 according to another embodiment of the present disclosure will be described with further reference to FIGS. 8 to 10. Those duplicate with the descriptions about the display device 1 according to the above-described embodiment will be omitted, and a difference therebetween will be mainly described.

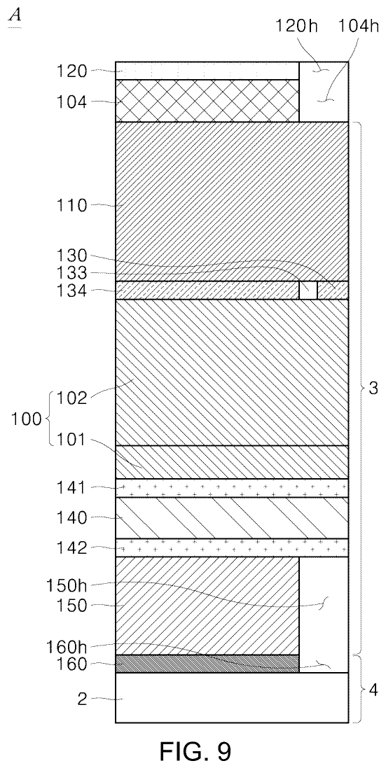

Referring to FIGS. 8 and 9, the touch panel 104 can be disposed on the polarizing layer 110. The touch panel 104 can be provided in a panel form separate from the display panel 100 and can have an add-on-type touch structure that is stacked on the polarizing layer 110. In this case, the touch panel 104 has a fourth opening 104h defined therein so as to overlap the first opening 120h in the vertical direction. However, embodiments of the present disclosure are not limited thereto, and in the touch panel 104, a separate opening may not be formed.

In this case, the front electrode 130, the antistatic layer 134, and the connection electrode layer 132 can be disposed between the polarizing layer 110 and the display panel 100. Accordingly, since the front electrode 130 can be disposed to be spaced apart from the touch panel 104 with the polarizing layer 110 interposed therebetween, signal interference caused by the touch panel 104 can be reduced.

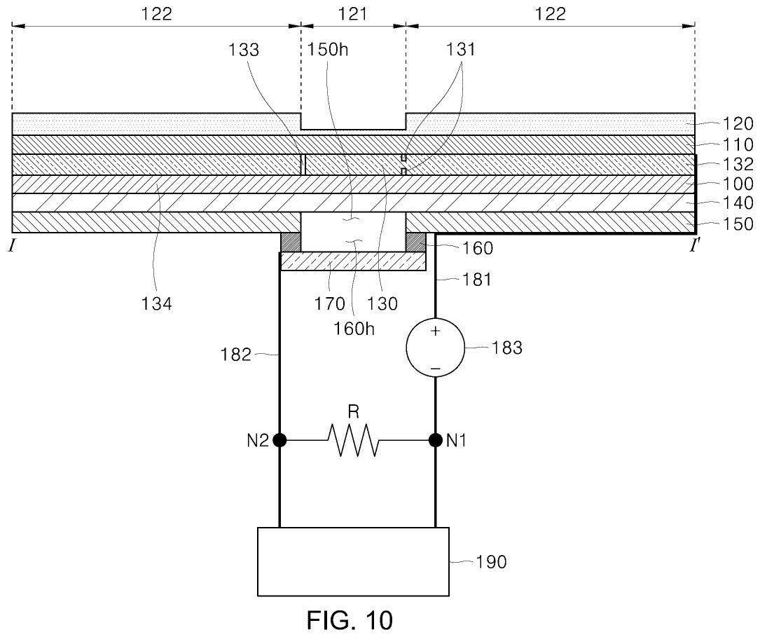

In addition, according to an embodiment of FIG. 10, the front electrode 130, the antistatic layer 134, and the connection electrode layer 132 can be disposed between the polarizing layer 110 and the display panel 100. In this case, the thickness of the first area 121 of the cover member 120 disposed to overlap the front electrode 130 in the vertical direction can be smaller than the thickness of the second area 122 of the cover member 120 in the vertical direction other than the first area 121 that does not overlap the front electrode 130 in the vertical direction.

As described above, the first area 121 of the cover member 120 is formed to have a small thickness without being entirely opened. Thus, the sound 40 can pass through the first area 121 of the cover member and can transmit vibration to the front electrode 130. Accordingly, the cover member 120 can prevent the polarizing layer 110 and the display panel 100 disposed thereunder from being exposed to the outside to protect the same, and can also serve to transmit vibration to the front electrode 130. The thickness of the first area 121 of the cover member 120 is sized such that the sound 40 can pass through the first area 121. In this regard, the thickness is not particularly limited. In this case, as in the embodiment according to FIG. 4, in order to maximize the vibration transfer from the sound to the front electrode 130, the first opening 120h can be formed in the cover member 120 by entirely opening the first area 121 of the cover member 120.

Although some embodiments of the present disclosure have been described above with reference to the accompanying drawings, the present disclosure may not be limited to some embodiments and can be implemented in various different forms. Those of ordinary skill in the technical field to which the present disclosure belongs will be able to appreciate that the present disclosure can be implemented in other specific forms without changing the technical idea or essential features of the present disclosure. Therefore, it should be understood that some embodiments as described above are not restrictive but illustrative in all respects.

What is claimed is:

1. A display device comprising:
a display panel;
a cover member disposed on the display panel;
a front electrode disposed on one side of the display panel;
an insulating layer disposed under the display panel;
a frame disposed under the insulating layer; and
a rear electrode disposed under the frame so as to face the front electrode,
wherein the cover member and the frame respectively include a first opening and a second opening, each of the first opening and the second opening disposed to overlap the front electrode in a vertical direction, and
wherein a change in capacitance between the front electrode and the rear electrode caused by a vibration of the front electrode is converted into an audio output signal.

2. The display device of claim 1, wherein the front electrode is disposed between the display panel and the insulating layer.

3. The display device of claim 2, further comprising a polarizing layer disposed between the cover member and the display panel,
wherein the polarizing layer, the display panel, and the insulating layer vibrate together with the vibration of the front electrode.

4. The display device of claim 3, further comprising a touch layer disposed between the display panel and the polarizing layer.

5. The display device of claim 3, wherein the display panel comprises a touch layer.

6. The display device of claim 1, wherein the front electrode is disposed between the cover member and the display panel.

7. The display device of claim 6, further comprising a polarizing layer disposed between the cover member and the front electrode,
wherein the polarizing layer, the display panel, and the insulating layer vibrate together with the vibration of the front electrode.

8. The display device of claim 7, further comprising a touch panel disposed between the polarizing layer and the cover member.

9. The display device of claim 1, further comprising an antistatic layer including a same material as the front electrode and disposed in a same layer,
wherein the front electrode is spaced apart from the antistatic layer by a predetermined distance.

10. The display device of claim 1, further comprising:
a first wiring electrically connected to the front electrode;
a connection electrode layer including a same material as and disposed in a same layer as the front electrode to electrically connect the front electrode to the first wiring; and
a second wiring electrically connected to the rear electrode,
wherein a notch is defined between the front electrode and the connection electrode layer, the notch having a thickness smaller than a thickness of each of the front electrode and the connection electrode layer.

11. The display device of claim 1, wherein the front electrode is a transparent electrode.

12. The display device of claim 1, wherein the display panel includes:
a display area;
a non-display area disposed outside the display area; and
a camera area disposed in the display area,
wherein the camera area is disposed closer to one side of the display area than to another side of the display area, and
wherein the first opening of the cover member is disposed adjacent to the camera area and is closer to one side of the display area than to another side of the display area.

13. The display device of claim 12, wherein a portion of the cover member corresponding to the camera area is unopened.

14. A display device comprising:
a display panel;
a cover member disposed on the display panel;
a front electrode disposed on one side of the display panel;
an antistatic layer including a same material as a material of the front electrode, wherein the antistatic layer and the front electrode are disposed in a same layer;
an insulating layer disposed under the display panel;
a rear electrode disposed under the insulating layer so as to face the front electrode; and
a microphone module configured to output a voltage between the front electrode and the rear electrode as an audio signal.

15. The display device of claim 14, wherein the front electrode is disposed between the display panel and the insulating layer.

16. The display device of claim 14, further comprising an adhesive layer disposed between the front electrode and the insulating layer,
wherein the front electrode is a deposition layer deposited on the display panel.

17. The display device of claim 14, wherein the front electrode is disposed between the cover member and the display panel.

18. The display device of claim 17, further comprising an adhesive layer disposed between the display panel and the insulating layer,
wherein the front electrode is a deposition layer deposited on the display panel.

19. The display device of claim 14, wherein the cover member has a first area overlapping the front electrode in a vertical direction, and
wherein a thickness of the first area in the vertical direction is smaller than a thickness of the cover member outside the first area of the cover member.

20. The display device of claim 14, wherein the cover member has a first area disposed to overlap the front electrode in a vertical direction, and
wherein the first area of the cover member is entirely opened.
